(19) United States
(12) Patent Application Publication
(10) Pub. No.: US 2013/0140625 A1
(43) Pub. Date: Jun. 6, 2013

(54) Field-Effect Transistor and Method of Making

(71) Applicants: Yinghua Piao, Shanghai (CN); Liang Ge, Shanghai (CN); Dongping Wu, Shanghai (CN); Shi-Li Zhang, Uppsala (SE); Wei Zhang, Shanghai (CN)

(72) Inventors: Yinghua Piao, Shanghai (CN); Liang Ge, Shanghai (CN); Dongping Wu, Shanghai (CN); Shi-Li Zhang, Uppsala (SE); Wei Zhang, Shanghai (CN)

(73) Assignee: FUDAN UNIVERSITY, Shanghai (CN)

(21) Appl. No.: 13/642,286

(22) PCT Filed: Apr. 25, 2011
(86) PCT No.: PCT/CN11/00729

§ 371 Date: Oct. 19, 2012

(30) Foreign Application Priority Data
Jun. 10, 2010 (CN) 201010197984.9

(51) Int. Cl. H01L 29/78; H01L 29/66

(52) U.S. Cl. CPC H01L 29/78; H01L 29/66477
USPC 257/327; 438/286

(57) ABSTRACT

The present invention belongs to the field of microelectronic device technologies. Specifically, an asymmetric source/drain field-effect transistor and its methods of making are disclosed. A structure of the field-effect transistor comprises: a semiconductor substrate, a gate structure, and a source region and a drain region having a mixed junction and a P-N junction, respectively. The source region and the drain region are asymmetrical structured with respect to each other, one of which comprises a P-N junction, and the other of which comprises a mixed junction, the mixed junction being a combination of a Schottky junction and a P-N junction. According to the present disclosure, a location of a doped region formed by ion implantation is controlled by adjusting an implantation angle, and a unique structure is formed for the asymmetric source/drain field-effect transistor.

### FIELD

The present invention belongs to the field of microelectronic device technologies, and is related to semiconductor devices and associated fabrication processes, and more particularly to field-effect transistors and method of making

### BACKGROUND

A MOS field-effect transistor (MOSFET), which is short for metal-oxide-semiconductor field-effect transistor, is a type of semiconductor device that uses the effect of electric field to control electric current in semiconductor. It is also called a unipolar transistor because it relies on one type of charge carriers to conduct electricity. MOS field-effect transistor can use semiconductor silicon or germanium as material. It can also be fabricated using compound semiconductor gallium arsenide as material. Currently, silicon is mostly used. A typical MOS field-effect transistor is comprised mainly of a semiconductor substrate, a source region, a drain region, a gate oxide later, and a gate electrode. Its basic structure is typically a four-terminal device, with a metal-insulator-semiconductor MOS capacitor structure in the middle and the source region and drain region on two sides of the MOS capacitor. In a normal “on” state, charge carriers can flow from the source and exit by the drain. Over the insulator layer is the gate. By applying a voltage on the gate, the intensity of the electric field in the insulator layer can be changed, and the electric field on the surface of the semiconductor can be controlled, so that the conductivity of a channel at the semiconductor surface can be changed.

The source region and the drain region of a typical MOS field-effect transistor are typically made of purely heavily doped P-N junction structures. This type of P-N junctions can be formed by doping regions in the semiconductor substrate corresponding to the source region and the drain with an appropriate amount of dopants using fabrication processes such as diffusion, ion implantation, etc. Field-effect transistors having such source/drain structures, however, have relatively high serial resistance and severe short-channel effects, and are difficult to miniaturize proportionally.

If metal-silicide source and drain are used to replace traditional heavily doped P-N junction source and drain, and are used in future ultra-miniaturized CMOS devices, the performance of the field-effect transistors can be enhanced to a certain degree. Metal-silicide source and drain refer to using metal silicides as the source and drain, the metal silicides forming Schottky junctions with the silicon substrate. Its main advantages are low parasitic resistance, good miniaturization characteristics, easy fabrication processes, low thermal budget, and strong anti latch-up or floating-body effect for silicon-on-insulator devices. Field-effect transistors having source/drain made of pure Schottky junctions, however, have many underlying problems. Schottky junctions often have extra leakage current and soft breakdown. Currently, the reliability of the field-effect transistors having this type of source/drain structures has not been properly studied.

A mixed junction is a combination of a Schottky junction and a P-N junction. It has the advantages of high operating current, fast switching speed, small leakage current, and high breakdown voltage, etc.

### SUMMARY

The present invention purports to provide a type of asymmetric source/drain field-effect transistor and methods of making The asymmetric source/drain field-effect transistor has high operating current, fast switching speed, and small leakage current.

According to embodiments of the present invention, the field-effect transistor comprises a semiconductor substrate, a gate structure, and a source region and a drain region having a mixed junction and a P-N junction, respectively. The source region and the drain region are asymmetrically structured with respect to each other, one of which comprises a P-N junction, and the other one of which comprises a mixed junction, the mixed junction being a combination of a Schottky junction and a P-N junction.

Preferably, the Schottky junction is formed by a metal-semiconductor compound contacting the semiconductor substrate, and the P-N junction is formed by implanting dopant ions into the semiconductor substrate followed by annealing, the dopant ions being of a type different from that of the semiconductor substrate.

Preferably, in the mixed junction, the metal-semiconductor compound forms a Schottky junction with the semiconductor substrate and an ohm contact with a highly doped region in one of the source region and the drain region in the semiconductor substrate.

Preferably, the semiconductor substrate includes silicon, germanium, silicon-germanium alloy, an SOI structure, or a GOI structure. The semiconductor substrate has a doping density between 1×10¹⁴ and 1×10¹⁹ cm⁻³.

Preferably, the field-effect transistor further comprises shallow trench structures formed in the semiconductor substrate and sidewall structures formed on two sides of the gate structure.

Preferably, the metal-semiconductor compound includes any of nickel silicide, nickel germanide, cobalt silicide, cobalt germanide, titanium silicide, titanium germanide, platinum silicide, and platinum germanide, or a combination of two or more thereof.

The present invention also purports to provide a method of making the above asymmetric source/drain field-effect transistor, comprising:
a) providing a semiconductor substrate, and forming isolation structures using shallow-trench isolation processes;
b) forming a first insulating dielectric layer, forming an electrode layer over the first insulting dielectric layer, and patterning and etching the electrode layer and the first insulating dielectric layer using photolithography and etching processes to form a gate structure, and source and drain regions on two sides of the gate structure;
c) depositing a second insulating dielectric layer;
d) etching the second insulating dielectric layer using a selective anisotropic etching process, thereby forming sidewall structures along two sides of the gate structure;
e) implanting ions and selecting an implanting angle α to cause the ions to reach part of one of the source region and the drain region, and performing annealing to activate implanted ions, thereby forming P-N junctions at the source region and the drain region;
f) depositing a metal layer, the metal layer reacting during annealing with exposed semiconductor substrate at the source region and the drain region to form a metal-semiconductor compound conductor layer, and removing part of the metal layer not having reacted with the semiconductor substrate.

A method of making the asymmetric field-effect transistor according to an alternative embodiment of the present invention comprises:
a) providing a semiconductor substrate, and forming isolation structures using shallow-trench isolation processes;
b) forming a first insulating dielectric layer, forming an electrode layer over the first insulting dielectric layer, and patterning and etching the electrode layer and the first insulator layer using photolithography and etching processes to form a gate structure, and source and drain regions on two sides of the gate structure;
c) performing first ion implantation and selecting an implanting angle α to cause ions to reach part of one of the source region and the drain region, and performing annealing to activate implanted ions, thereby forming P-N junctions at the source region and the drain region;
d) depositing a second insulating dielectric layer;
e) etching the second insulating dielectric layer using a selective anisotropic etching process, thereby forming sidewall structures along two sides of the gate structure, the sidewall structures having a thickness smaller than a product of a height of the gate structure and tan α;
f) depositing a metal layer, the metal layer reacting during annealing with exposed semiconductor substrate at the source region and the drain region to form a metal-semiconductor compound conductor layer, and removing part of the metal layer not having reacted with the semiconductor substrate.

Preferably, the semiconductor substrate in the above methods includes silicon, germanium, silicon-germanium alloy, an SOI structure, or a GOI structure.

Preferably, the first insulating dielectric layer in the above methods includes silicon dioxide, silicon nitride, aluminum oxide, or hafnium-based high dielectric constant dielectric material.

Preferably, the electrode layer in the above methods includes at least one conductor layer, the conductor layer including any of polysilicon, titanium nitride, tantalum nitride, tungsten, and metal silicide, or a multilayer structure of two or more thereof

Preferably, a peak dopant density formed by implanting ions into the semiconductor substrate in the above methods is not lower than 1×10¹⁹ cm⁻³.

Preferably, the metal layer in the above methods includes any of nickel, cobalt, titanium, and platinum, or a combination of two or more thereof.

Preferably, the metal-semiconductor compound conductor layer in the above methods includes any of nickel silicide, nickel germanide, cobalt silicide, cobalt germanide, titanium silicide, titanium germanide, platinum silicide, and platinum germanide, or a combination of two or more thereof.

The field-effect transistor provided by the present invention has the advantages of high operating current, fast switching speed, small leakage current, and high breakthrough voltage,

These objectives, together with the subjects and features of the present invention will be explained in further detail below with reference to the drawings.

### BRIEF DESCRIPTION OF THE DRAWINGS

FIG. 1 is a cross-sectional diagram illustrating a semiconductor substrate after forming shallow-trench isolation structures according to one embodiment of the present invention.

FIG. 2 is a cross-sectional diagram illustrating forming a first insulating dielectric layer and the electrode layer on the semiconductor substrate subsequent to what is shown in FIG. 1.

FIG. 3 is a cross-sectional diagram illustrating forming a gate structure using photolithography and etching subsequent to what is shown in FIG. 2.

FIG. 4 is a cross-sectional diagram illustrating forming a second insulating dielectric layer by deposition subsequent to what is shown in FIG. 3.

FIG. 5 is a cross-sectional diagram illustrating forming sidewall structures by etching subsequent to what is shown in FIG. 4.

FIG. 6 is a cross-sectional diagram illustrating ion implantation and annealing subsequent to what is shown in FIG. 5.

FIG. 7 is a cross-sectional diagram illustrating depositing a metal layer subsequent to what is shown in FIG. 6.

FIG. 8 is a cross-sectional diagram illustrating the asymmetric source/drain field-effect transistor formed after annealing and removing the metal layer subsequent to what is shown in FIG. 7.

FIG. 9 is a cross-sectional diagram illustrating ion implantation and annealing subsequent to what is shown in FIG. 3.

FIG. 10 is a cross-sectional diagram illustrating forming a second insulating dielectric layer by deposition subsequent to what is shown in FIG. 9.

FIG. 11 is a cross-sectional diagram illustrating forming sidewall structures using an etching step subsequent to what is shown in FIG. 10.

FIG. 12 is a cross-sectional diagram illustrating depositing a metal layer subsequent to what is shown in FIG. 11.

FIG. 13 is a cross-sectional diagram illustrating the asymmetric source/drain field-effect transistor after annealing and removing the metal layer subsequent to what is shown in FIG. 12.

### DETAILED DESCRIPTION OF THE EMBODIMENTS

An asymmetric source/drain field-effect transistor structure and method of making, as provided by embodiments of the present invention, are described in more detail below with reference to the drawings. In the following description, same reference numerals are used to denote same components and repeated descriptions are omitted. In the drawings, for ease of explanation, the sizes of different layers and regions are enlarged or diminished. Therefore, the illustrated sizes may not represent the actual sizes, or their proportions.

It should be noted that, without departing from the spirit and scope of the present invention, many largely different embodiments could be constructed. It is to be understood that, except for the limitations in the appended claims, the present invention is not limited to the specific embodiments in the present disclosure.

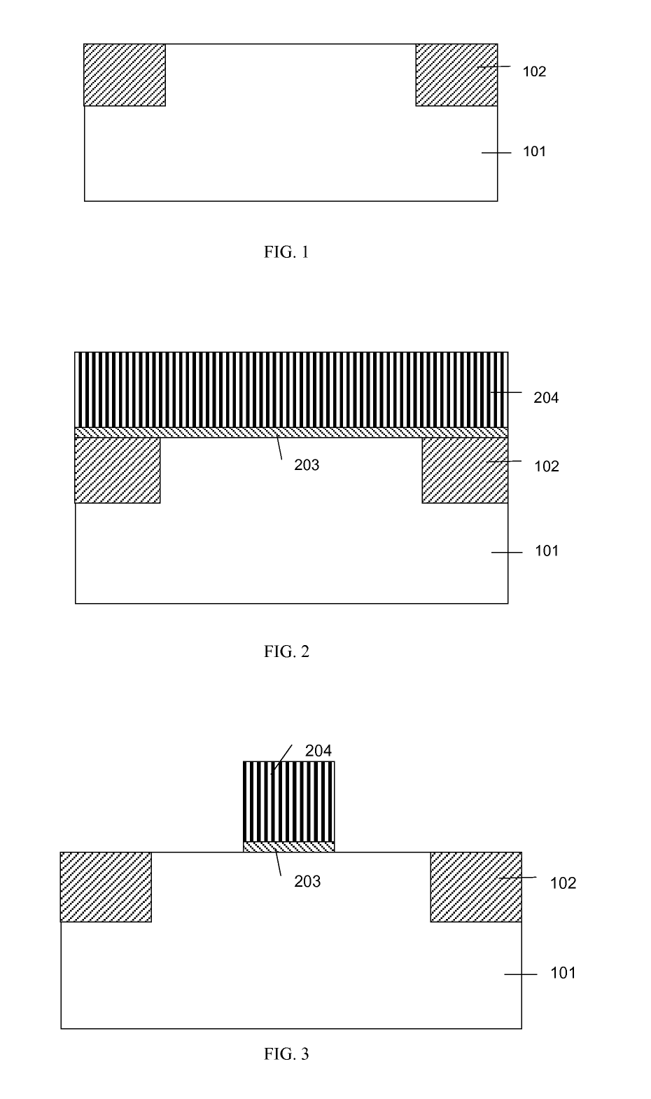

FIG. 1 is a cross-sectional diagram illustrating a semiconductor substrate after shallow-trench isolation structures are formed, according to one embodiment of the present invention. A silicon substrate 101 is prepared and pre-growth processes such as cleaning and removal of native oxide layer on the silicon surface, etc., are completed. In this embodiment, the semiconductor substrate is single crystal silicon. Afterwards, shallow trench isolation processes are used to fabricate isolation structures 102 around a transistor area.

As shown in FIG. 2, a first insulating dielectric layer 203 is formed on the substrate. Afterwards, an electrode layer 204 is formed over the first insulating dielectric layer 203.

As shown in FIG. 3, the first insulating dielectric layer is patterned using photolithography and etching processes, thereby forming a gate structure and the source region and drain region on two sides of the gate structure.

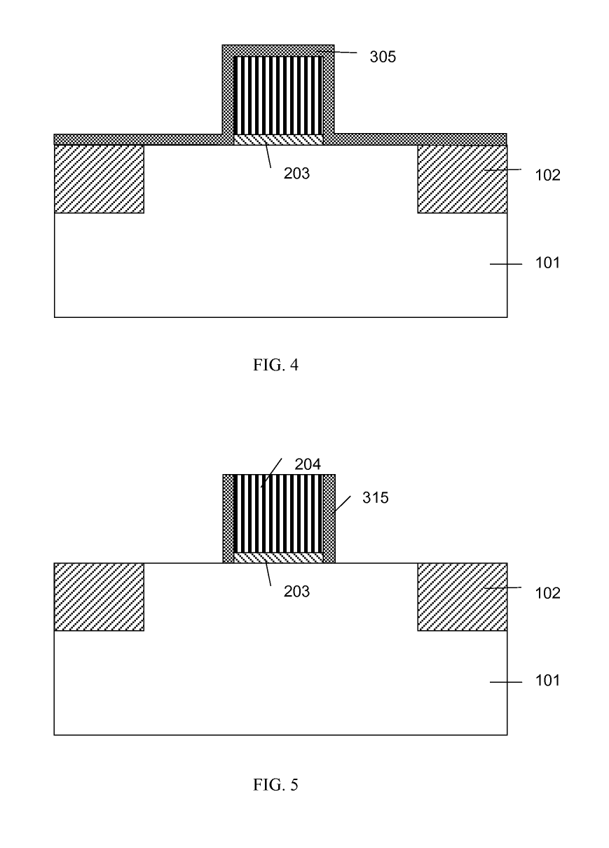

As shown in FIG. 4, a second insulating dielectric layer 305 is formed by deposition. Afterwards, the insulating dielectric layer is anisotropically etched using a dry-etching process, thereby forming sidewall structures 315 along two sides of the gate structure, as shown in cross-section in FIG. 5.

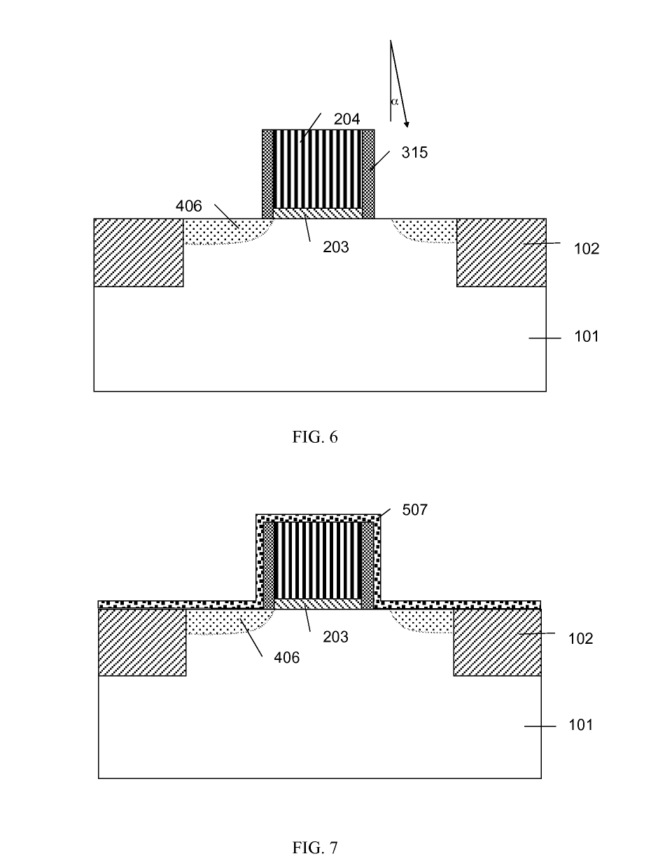

As shown in FIG. 6, ions are implanted using a selected implanting angle α to cause ions to reach part of the source region or the drain region Annealing is performed afterwards to activate the implanted ions, thereby forming regions 406 in the substrate that are oppositely doped with respect to the substrate, the doped regions 406 forming P-N junctions with the substrate 101.

As shown in FIG. 7, a metal layer 507 is deposited on the substrate. Layer 507 includes any of nickel, cobalt, titanium, and platinum, or a combination of two or more thereof. During annealing, layer 507 reacts with exposed substrate at the source region and the drain region to form a metal-semiconductor compound.

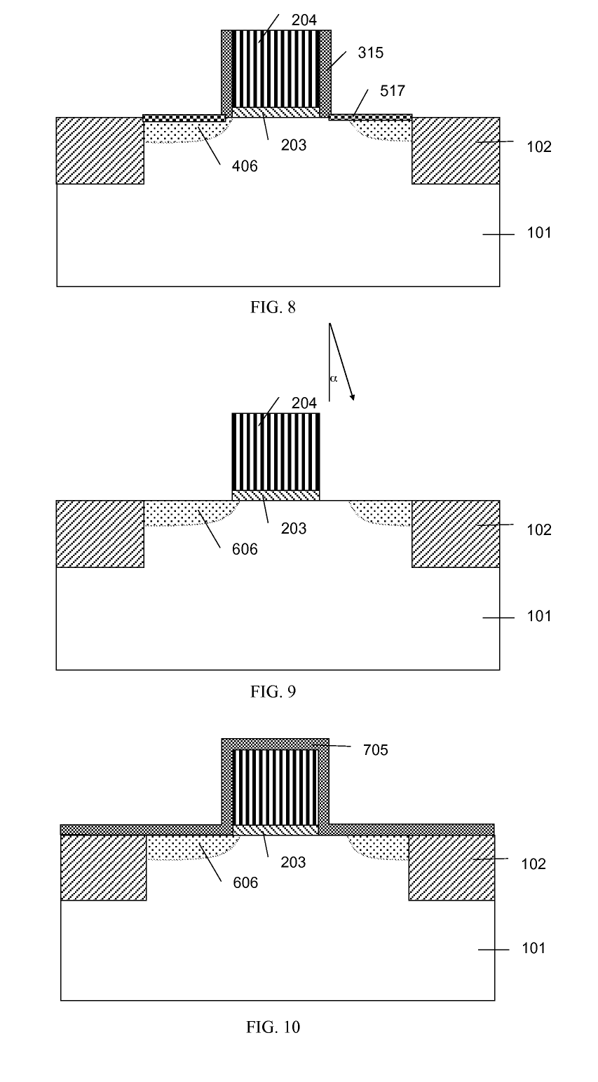

As shown in FIG. 8, after removing unreacted part of the metal layer 507, the metal-semiconductor compound layer 517 is exposed. Layer 517 includes any of nickel silicide, nickel germanide, cobalt silicide, cobalt germanide, titanium silicide, titanium germanide, platinum silicide, and platinum germanide, or a combination of two or more thereof. Without departing from the spirit of the present invention, other processes or methods can also be used to form conductor layer 517.

A method of making an asymmetric source/drain field-effect transistor according to an alternative embodiment of the present invention is described below.

FIG. 1 is a cross-sectional diagram illustrating a semiconductor substrate after shallow-trench isolation structures are formed, according to one embodiment of the present invention. A silicon substrate 101 is prepared and pre-growth processes such as cleaning and removal of native oxide layer on the silicon surface, etc., are completed. In this embodiment, the semiconductor substrate is single crystal silicon. Afterwards, shallow trench isolation processes are used to fabricate isolation structures 102 around a transistor area.

As shown in FIG. 2, a first insulating dielectric layer 203 is formed on the substrate. Afterwards, an electrode layer 204 is formed over the first insulating dielectric layer 203.

As shown in FIG. 3, the first insulating dielectric layer is patterned using photolithography and etching processes, thereby forming a gate structure and the source region and drain region on two sides of the gate structure.

As shown in FIG. 9, ions are implanted using a selected implanting angle α to cause the ions to reach part of the source region or the drain region Annealing is performed afterwards to activate the implanted ions, thereby forming regions 606 in the substrate that are oppositely doped with respect to the substrate, the doped regions 606 forming P-N junctions with the substrate 101.

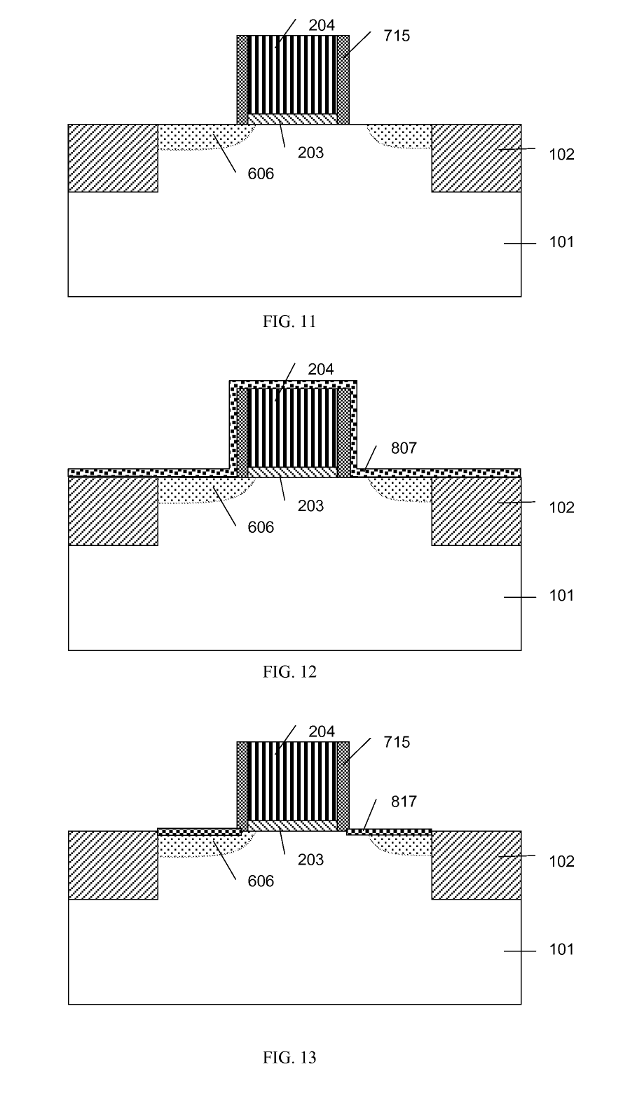

As shown in FIG. 10, a second insulating dielectric layer 705 is formed by deposition. Afterwards, the insulating dielectric layer is anisotropically etched using a dry-etching process, thereby forming sidewall structures 715 along two sides of the gate structure. Layer 715 has a thickness that should be smaller than a product of a height of the gate structure and tan α, so as to ensure that part of the substrate 101 would be uncovered, as shown in cross-section in FIG. 11.

As shown in FIG. 12, a metal layer 807 is deposited on the substrate. Layer 807 includes any of nickel, cobalt, titanium, and platinum, or a combination of two or more thereof. During annealing, layer 807 reacts with exposed substrate at the source region and the drain region to form a metal-semiconductor compound.

As shown in FIG. 13, after removing unreacted part of the metal layer 807, the metal-semiconductor compound layer 817 is exposed. Layer 817 forms a Schottky junction with substrate 101 and an ohm contact with region 606. Layer 817 includes any of nickel silicide, nickel germanide, cobalt silicide, cobalt germanide, titanium silicide, titanium germanide, platinum silicide, and platinum germanide, or a combination of two or more thereof. Without departing from the spirit of the present invention, other processes or methods can also be used to form a conductor layer 817.

1. A field-effect transistor structure, comprising: a semiconductor substrate, a gate structure, and a source region, and a drain region, wherein the source region and the drain region are asymmetrically structured with respect to each other, one of the source region and drain region comprising a first P-N junction, and the other one of the source region and drain region comprising a mixed junction, the mixed junction being a combination of a Schottky junction and a second P-N junction.

2. A field-effect transistor according to claim 1, wherein the Schottky junction is formed by a metal-semiconductor compound contacting the semiconductor substrate, and each of the first and second P-N junction is formed by implanting dopant ions into the semiconductor substrate followed by annealing, the dopant ions being of a type different from that of the semiconductor substrate.

3. A field-effect transistor according to claim 2, wherein, in the mixed junction, the metal-semiconductor compound forms a Schottky junction with the semiconductor substrate and an ohm contact with a highly-doped region in one of the source region and the drain region in the semiconductor substrate.

4. A field-effect transistor according to claim 1, wherein the semiconductor substrate includes silicon, germanium, silicon-germanium alloy, an SOI structure, or a GOI structure, the semiconductor substrate having a doping density between 1×10¹⁴ and 1×10¹⁹ cm⁻³.

5. A field-effect transistor according to claim 1, wherein the field-effect transistor further comprises shallow trench isolation structures formed in the semiconductor substrate and sidewall structures formed on two sides of the gate structure.

6. A field-effect transistor according to claim 3, wherein the metal-semiconductor compound includes any of nickel silicide, nickel germanide, cobalt silicide, cobalt germanide, titanium silicide, titanium germanide, platinum silicide, and platinum germanide, or a combination of two or more thereof.

7. A method of making the field-effect transistor according to claim 1, comprising:
forming the gate structure over the semiconductor substrate;
forming sidewall structures along two sides of the gate structure;
implanting ions at an implanting angle α such that an area of one of the source region and the drain region is not implanted with ions, and performing annealing to activate implanted ions, thereby forming highly-doped regions at the source region and the drain region; and
forming a metal-semiconductor compound conductor layer, the metal-semiconductor compound conductor layer forming a Schottky junction with the area of the semiconductor substrate in the one of the source region and the drain region and an ohm contact with each of the highly-doped regions.

8. A method of making a field-effect transistor, comprising:
forming a gate structure over a semiconductor substrate, the gate structure disposed between a first substrate region on a first side of the gate structure and a second substrate region on a second side of the gate structure;
implanting ions at an angle α to form a first highly-doped region in the first substrate region and a second highly-doped region in a first part of the second substrate region; and
depositing a metal layer, the metal layer reacting during annealing with semiconductor in the first substrate region and the second substrate region to form a first metal-semiconductor compound conductor layer over the first substrate region and a second metal-semiconductor compound conductor layer over the second substrate region, the second metal-semiconductor compound conductor layer forming an ohm contact with the second highly-doped region and a Schottky junction with a second part of the second substrate region.

9. The method of making a field-effect transistor according to claim 8, wherein the semiconductor substrate is selected from the group consisting of silicon, germanium, silicon-germanium alloy, an SOI structure, and a GOI structure, and wherein the first insulating dielectric layer includes silicon dioxide, silicon nitride, aluminum oxide, or hafnium-based high dielectric constant dielectric material.

10. The method of making a field-effect transistor according to claim 8, wherein the gate structure includes an electrode layer having at least one conductor layer, the conductor layer including any of polysilicon, titanium nitride, tantalum nitride, tungsten, and metal silicide, or a multilayer structure of two or more thereof.

11. The method of making a field-effect transistor according to claim 8, wherein a peak dopant density in the first and second highly-doped regions is not lower than 1×10¹⁹ cm⁻³.

12. The method of making a field-effect transistor according to claim 8, characterized in that the first or second metal layer includes any of nickel, cobalt, titanium, and platinum, or a combination of two or more thereof.

13. The method of making a field-effect transistor according to claim 8, characterized in that the first or second metal-semiconductor compound conductor layer includes any of nickel silicide, nickel germanide, cobalt silicide, cobalt germanide, titanium silicide, titanium germanide, platinum silicide, and platinum germanide, or a combination of two or more thereof.

14. The method of making a field-effect transistor according to claim 8, further comprising forming sidewall structures on two sides of the gate structure before implanting the ions.

15. The method of making a field-effect transistor according to claim 8, further comprising forming sidewall structures on two sides of the gate structure after implanting the ions, the sidewall structures having a thickness less than a product of a height of the gate structure and tan α.

16. A method of making the field-effect transistor according to claim 1, comprising:
forming the gate structure over the semiconductor substrate;
implanting ions at an implanting angle α such that an area of of the semiconductor substrate in one of the source region and the drain region is not implanted with ions, and performing annealing to activate implanted ions, thereby forming highly-doped regions at the source region and the drain region;
forming sidewall structures along two sides of the gate structure, the sidewall structures having a thickness smaller than a product of a height of the gate structure and tan α;
forming a metal-semiconductor compound conductor layer, the metal-semiconductor compound conductor layer forming a Schottky junction with the area of the semiconductor substrate in the one of the source region and the drain region and an ohm contact with each of the highly-doped regions.

17. A field-effect transistor, comprising:
a gate structure over a semiconductor substrate, the gate structure disposed between a first substrate region on a first side of the gate structure and a second substrate region on a second side of the gate structure;
a first highly-doped region in the first substrate region;
a second highly-doped region in a first part of the second substrate region; and
a metal-semiconductor compound conductor layer over the second substrate region, the metal-semiconductor compound conductor layer forming an ohm contact with the second highly-doped region and a Schottky junction with a second part of the second substrate region.

18. The field-effect transistor according to claim 1, further comprising:
a metal-semiconductor compound conductor layer over the first substrate region and forming an ohm contact with the first highly-doped region

19. The field-effect transistor according to claim 1, wherein the second part of the second substrate region is closer to the gate structure than the first part of the second substrate region.

20. The field-effect transistor according to claim 1, wherein one of the first and second substrate regions is a source region and the other one of the first and second substrate regions is a drain region.
